(19) United States
(12) Patent Application Publication
(10) Pub. No.: US 2025/0239980 A1
(43) Pub. Date: Jul. 24, 2025

(54) METHOD OF MANUFACTURING ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Naohiro NODAKE, Nagaokakyo-shi (JP)

(21) Appl. No.: 19/021,401

(22) Filed: Jan. 15, 2025

(30) Foreign Application Priority Data
Jan. 23, 2024 (JP) 2024-008223

(51) Int. Cl. H03H 3/08; H03H 9/02; H03H 9/25

(52) U.S. Cl. CPC H03H 3/08; H03H 9/02559; H03H 9/25

(57) ABSTRACT

A method of manufacturing an acoustic wave device includes preparing a substrate, preparing a support, providing a buffer layer on the substrate, providing a piezoelectric film on the buffer layer, joining the piezoelectric film of a multilayer body including the substrate, the buffer layer, and the piezoelectric film to the support, and removing the buffer layer and the substrate from the piezoelectric film. (|LS−LB|/LS)×100[%]≤20[%], and (|LP−LB|/LP)×100[%]≤10[%], where LS is a lattice constant of the substrate, LB is a lattice constant of the buffer layer, and LP is a lattice constant of the piezoelectric film.

### CROSS REFERENCE TO RELATED APPLICATIONS

This application claims the benefit of priority to Japanese Patent Application No. 2024-008223 filed on Jan. 23, 2024. The entire contents of this application are hereby incorporated herein by reference.

### BACKGROUND OF THE INVENTION

### 1. Field of the Invention

The present invention relates to methods of manufacturing acoustic wave devices.

### 2. Description of the Related Art

Acoustic wave devices have been widely used in filters of mobile phones and other applications. Japanese Unexamined Patent Application Publication No. 2023-180558 describes examples of an acoustic wave device and its manufacturing method. In the manufacturing method described in Japanese Unexamined Patent Application Publication No. 2023-180558, a piezoelectric substrate is prepared as a piezoelectric layer. However, in the stage when the piezoelectric layer is prepared, the thickness of the piezoelectric layer is not a desired thickness. Hence, in this manufacturing method, the piezoelectric layer is ground to be a thin film, so that the thickness of the piezoelectric layer is adjusted to a desired thickness.

### SUMMARY OF THE INVENTION

However, in a manufacturing method of the related art as described in Japanese Unexamined Patent Application Publication No. 2023-180558, most of the prepared piezoelectric layer is sometimes removed by grinding and discarded. Hence, it is difficult to achieve sufficient productivity. However, in the method of the related art, to achieve a sufficient crystallinity of a piezoelectric layer in a thin film shape to be used in the acoustic wave device, a piezoelectric substrate having high crystallinity needs to be prepared, and then, the piezoelectric substrate needs to be processed to be in a thin film shape.

Example embodiments of the present invention provide methods of manufacturing acoustic waves device, which results in increasing the crystallinity of the piezoelectric film and also increasing the productivity.

A method of manufacturing an acoustic wave device according to an example embodiment of the present invention includes preparing a substrate, preparing a support, providing a buffer layer on the substrate, providing a piezoelectric film on the buffer layer, joining the piezoelectric film of a multilayer body including the substrate, the buffer layer, and the piezoelectric film to the support, and removing the buffer layer and the substrate from the piezoelectric film. (|LS−LB|/LS)×100[%]≤20[%], and (|LP−LB|/LP)×100[%]≤10[%], where LS is a lattice constant of the substrate, LB is a lattice constant of the buffer layer, and LP is a lattice constant of the piezoelectric film.

With methods of manufacturing acoustic wave devices according to example embodiments of the present invention, it is possible to increase the crystallinity of the piezoelectric film and also increase the productivity.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 a schematic elevational sectional view of an acoustic wave device according to a first example embodiment of the present invention.

FIG. 2 is a schematic plan view of the acoustic wave device according to the first example embodiment of the present invention.

FIGS. 3A to 3D are schematic elevational sectional views for explaining a first example embodiment of a method of manufacturing an acoustic wave device according to the present invention.

FIGS. 4A and 4B are simplified elevational sectional views for explaining the first example embodiment of the method of manufacturing the acoustic wave device according to the present invention.

FIGS. 5A and 5B are schematic elevational sectional views for explaining a step of irradiating a buffer layer with laser light and related processes in a first modification example of the first example embodiment of the method of manufacturing the acoustic wave device according to the present invention.

FIGS. 6A and 6B are schematic elevational sectional views for explaining a step of removing the buffer layer and a substrate from a piezoelectric film and related processes in the first modification example of the first example embodiment of the method of manufacturing the acoustic wave device according to the present invention.

FIGS. 7A and 7B are schematic elevational sectional views for explaining a second modification example of the first example embodiment of the method of manufacturing the acoustic wave device according to the present invention.

FIG. 8 is a schematic view of a hexagonal crystal structure, illustrating an a-plane, an m-plane, a c-plane, and an r-plane.

FIG. 9 is a schematic elevational sectional view of an acoustic wave device according to a second example embodiment of the present invention.

FIGS. 10A to 10C are schematic elevational sectional views for explaining a second example embodiment of a method of manufacturing the acoustic wave device according to the present invention.

FIGS. 11A to 11D are simplified elevational sectional views for explaining the second example embodiment of the method of manufacturing the acoustic wave device according to the present invention.

FIG. 12 is a schematic elevational sectional view of an acoustic wave device according to a third example embodiment of the present invention.

FIGS. 13A to 13C are schematic elevational sectional views for explaining a step of preparing a support in a third example embodiment of a method of manufacturing an acoustic wave device according of the present invention.

FIGS. 14A and 14B are schematic elevational sectional views for explaining a step of joining a piezoelectric film to the support and a step of removing a buffer layer and a substrate from the piezoelectric film in the third example embodiment of the method of manufacturing the acoustic wave device according to the present invention.

FIG. 15 is a schematic elevational sectional view of an acoustic wave device according to a fourth example embodiment of the present invention.

FIGS. 16A to 16D are schematic elevational sectional views for explaining a fourth example embodiment of a method of manufacturing the acoustic wave device according to the present invention.

### DETAILED DESCRIPTION OF THE EXAMPLE EMBODIMENTS

Hereinafter, specific example embodiments of the present invention will be described with reference to the drawings, so that the present invention will be clearly understood.

Note that each example embodiment described in the present specification is a mere example, and hence, elements, steps, characteristics, features, etc., can be partially replaced or combined between different example embodiments.

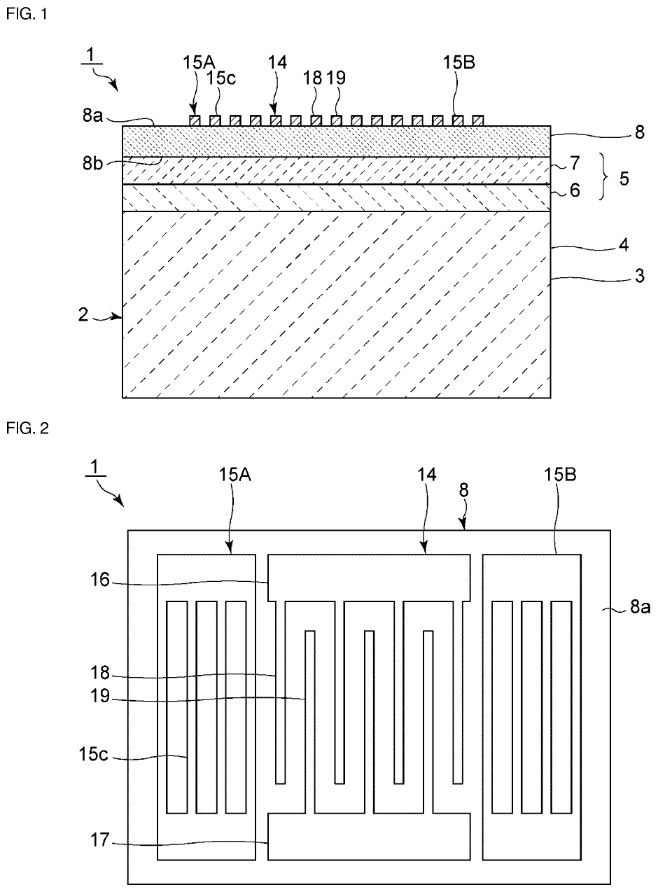

FIG. 1 is a schematic elevational sectional view of an acoustic wave device according to a first example embodiment of the present invention.

An acoustic wave device 1 includes a piezoelectric substrate 2 and a functional electrode 14. The piezoelectric substrate 2 is a substrate having piezoelectricity. Specifically, the piezoelectric substrate 2 includes a support 3 and a piezoelectric film 8. In the present example embodiment, the support 3 includes a support substrate 4 and an intermediate layer 5. The intermediate layer 5 is a multilayer body including two dielectric layers. More specifically, the intermediate layer 5 includes a first layer 6 and a second layer 7. The first layer 6 is located on the support substrate 4. The second layer 7 is located on the first layer 6. The piezoelectric film 8 is located on the second layer 7. Note that the intermediate layer 5 may be, for example, a single dielectric layer.

The piezoelectric film 8 includes a first main surface 8a and a second main surface 8b. The first main surface 8a and the second main surface 8b are opposed to each other. Of the first main surface 8a and the second main surface 8b, the second main surface 8b faces the support 3.

FIG. 2 is a schematic plan view of the acoustic wave device according to the first example embodiment.

The first main surface 8a of the piezoelectric film 8 is provided with the functional electrode 14. In the present example embodiment, the functional electrode 14 is an interdigital transducer (IDT) electrode. The functional electrode 14 includes a pair of busbars and pluralities of electrode fingers. The pair of busbars includes, specifically, a first busbar 16 and a second busbar 17. The first busbar 16 and the second busbar 17 face each other. The pluralities of electrode fingers are, specifically, a plurality of first electrode fingers 18 and a plurality of second electrode fingers 19. One end of each of the first electrode fingers 18 is connected to the first busbar 16. One end of each of the second electrode fingers 19 is connected to the second busbar 17. The plurality of first electrode fingers 18 and the plurality of second electrode fingers 19 interdigitate with one another.

Hereinafter, sometimes, the first electrode fingers 18 and the second electrode fingers 19 are collectively simply referred to as the electrode fingers. The direction in which the plurality of electrode fingers extend is referred to as the electrode-finger extension direction, and the direction orthogonal to the electrode-finger extension direction is referred to as the electrode-finger orthogonal direction.

The first main surface 8a of the piezoelectric film 8 is provided with a pair of a reflector 15A and a reflector 15B. The reflector 15A and the reflector 15B are on respective sides of the functional electrode 14 in the electrode-finger orthogonal direction and face each other. The reflector 15A includes a plurality of electrode fingers 15c. In the reflector 15A, both ends of each of the electrode fingers 15c are electrically short-circuited. The reflector 15B has a configuration the same as or similar to that of the reflector 15A. The functional electrode 14, the reflector 15A, and the reflector 15B may include a single-layered metal film or a laminated metal film. Note that the reflector 15A and the reflector 15B are optional.

When an alternating current voltage is applied to the functional electrode 14, acoustic waves are generated through excitation. The acoustic wave device 1 is a surface acoustic wave resonator. However, the acoustic wave that the acoustic wave device 1 use as a main mode is not limited to surface acoustic waves. For example, the acoustic wave device 1 may be configured to use bulk waves of thickness shear mode as the main mode. In this case, it is preferable that d/p be about 0.5 or less, for example, when d is defined as the thickness of the piezoelectric film 8, and p as the center distance of adjacent ones of the first electrode fingers 18 and the second electrode fingers 19. This enables the thickness shear mode to be excited favorably.

Acoustic wave devices 1 can be obtained, for example, by singulating a wafer including a plurality of functional electrodes 14 into individual pieces. The substrates obtained by singulating a wafer into individual pieces are piezoelectric substrates 2.

The following describes an example of a method of manufacturing the acoustic wave device 1. This manufacturing method is a first example embodiment of a method of manufacturing an acoustic wave device according to the present invention.

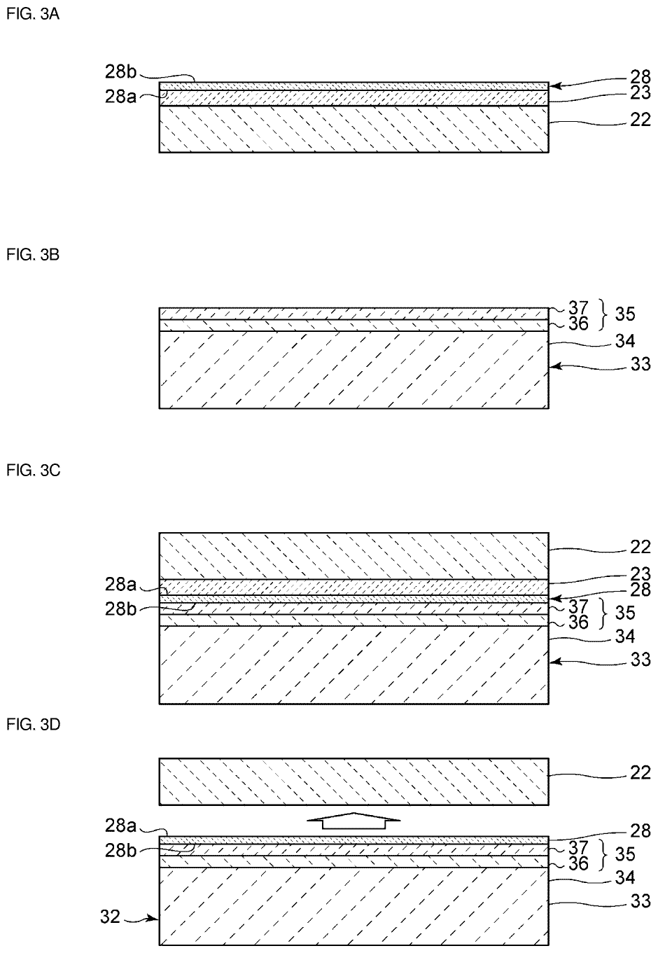

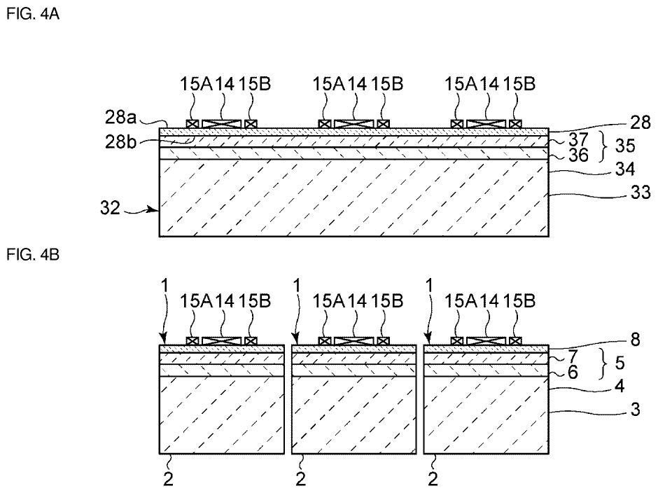

FIGS. 3A to 3D are schematic elevational sectional views for explaining the first example embodiment of the method of manufacturing the acoustic wave device according to the present invention. FIGS. 4A and 4B are simplified elevational sectional views for explaining the first example embodiment of the method of manufacturing the acoustic wave device. In FIGS. 4A and 4B, the functional electrode 14, the reflector 15A, and the reflector 15B are each represented by a simplified figure including a rectangle and two diagonal lines. The same is true of other simplified elevational sectional views.

As illustrated in FIG. 3A, a substrate 22 is prepared. Next, a buffer layer 23 is provided on the substrate 22. In this process, the buffer layer 23 is formed, for example, on the substrate 22 by epitaxial growth. In this case, the buffer layer 23 can be formed, for example, by hydride vapor phase epitaxy (HVPE), metal organic chemical vapor deposition (MOCVD), or the like. In the present example embodiment, the buffer layer 23 is an epitaxial layer.

In this specification, the term “epitaxial layer” refers to a layer including an epitaxially grown alignment film. In addition, in this specification, the term “epitaxially grown alignment film” refers to a single-crystal film or a polycrystalline film with a twin crystal structure. Whether a layer is an epitaxial layer or not can be checked by performing pole figure measurement using an X-ray diffraction method. When the layer has a twin crystal structure, the diffraction pattern has a plurality of symmetry centers. This means that the layer is an epitaxial layer.

Next, a piezoelectric film 28 is provided on the buffer layer 23. In this process, the piezoelectric film 28 is formed, for example, on the buffer layer 23 by epitaxial growth. In this case, for example, the piezoelectric film 28 can be formed by HVPE, MOCVD, or the like. In the present example embodiment, the piezoelectric film 28 is an epitaxial layer. Note that the piezoelectric film 28 is singulated in a later step into individual piezoelectric films 8 one of which is illustrated in FIG. 1.

The piezoelectric film 28 includes a first main surface 28a and a second main surface 28b. The first main surface 28a and the second main surface 28b are opposed to each other. Of the first main surface 28a and the second main surface 28b, the first main surface 28a faces the buffer layer 23.

Separately from these processes, a support 33 is prepared as illustrated in FIG. 3B. The support 33 is singulated in a later step into individual supports 3 one of which is illustrated in FIG. 1. In the step of preparing the support 33 illustrated in FIG. 3B, first, a support substrate 34 is prepared. Next, an intermediate layer 35 is provided on the support substrate 34. More specifically, a first layer 36 is provided on the support substrate 34. Next, a second layer 37 is provided on the first layer 36. The first layer 36 is a silicon nitride layer in the present example embodiment. The second layer 37 is a silicon oxide layer in the present example embodiment. The first layer 36 and the second layer 37 can be formed, for example, by sputtering, vacuum vapor deposition, or the like.

Next, as illustrated in FIG. 3C, the piezoelectric film 28 of a multilayer body including the substrate 22, the buffer layer 23, and the piezoelectric film 28 is joined to the support 33. Specifically, in the present example embodiment, the second main surface 28b of the piezoelectric film 28 is joined to the intermediate layer 35 of the support 33.

Next, the buffer layer 23 and the substrate 22 are removed from the piezoelectric film 28 by wet etching. Specifically, the buffer layer 23 is removed by wet etching, and the substrate 22 is separated from the piezoelectric film 28 as illustrated in FIG. 3D. With this process, a wafer 32 is obtained. More specifically, the wafer 32 is a multilayer body including the support 33 and the piezoelectric film 28. Note that to remove the buffer layer 23 and the substrate 22 from the piezoelectric film 28, for example, laser lift-off or the like may be used.

Next, the first main surface 28a of the piezoelectric film 28 is cleaned. The first main surface 28a is the main surface of the piezoelectric film 28 on which the buffer layer 23 illustrated in FIG. 3C was laminated. In some cases, the buffer layer 23 is not completely removed from the first main surface 28a. This cleaning removes the buffer layer 23 more reliably from the first main surface 28a. This in turn reduces defects resulting from the residue of the buffer layer 23, increasing the productivity. However, the cleaning of the first main surface 28a is optional.

Next, high-temperature heat treatment or discharge treatment is performed on the piezoelectric film 28. This enables alignment of the polarization state of the piezoelectric film 28 more reliably. However, the high-temperature heat treatment or discharge treatment of the piezoelectric film 28 is optional.

Next, the arithmetic mean roughness Ra of the first main surface 28a of the piezoelectric film 28 is adjusted. The adjustment of the arithmetic mean roughness Ra of the first main surface 28a can be performed, for example, by polishing or the like. In this case, for example, chemical mechanical polishing (CMP) or the like may be used. It is preferable that the arithmetic mean roughness Ra of the first main surface 28a be about 1 nm or less, for example. This enables the obtained acoustic wave device 1 to achieve favorable electrical characteristics. Note that the arithmetic mean roughness in the present specification is based on arithmetic mean roughness Ra in JIS B 0601:2001. However, the step of adjusting the arithmetic mean roughness Ra of the first main surface 28a of the piezoelectric film 28 is optional.

Next, as illustrated in FIG. 4A, a plurality of functional electrodes 14, a plurality of reflectors 15A, and a plurality of reflectors 15B are provided on the first main surface 28a of the piezoelectric film 28. Note that in addition to the functional electrodes 14 and the reflectors, wiring may be provided on the first main surface 28a when the functional electrodes 14 and the reflectors are provided. The functional electrodes 14, the reflectors, and the wiring can be formed, for example, by photolithography or the like using sputtering or vacuum vapor deposition.

Next, the wafer 32 is singulated into individual pieces. The wafer 32 can be singulated into individual pieces, for example, by cutting with a dicing machine or other methods. A plurality of acoustic wave devices 1 can be obtained by this process, as illustrated in FIG. 4B.

Hereinafter, in FIG. 3A, LS is defined as the lattice constant of the substrate 22, LB as the lattice constant of the buffer layer 23, and LP as the lattice constant of the piezoelectric film 28. A mismatch between the lattice constant LS of the substrate 22 and the lattice constant LB of the buffer layer 23 is defined as (|LS−LB|/LS)×100[%], for example, and a mismatch between the lattice constant LB of the buffer layer 23 and the lattice constant LP of the piezoelectric film 28 as (|LP−LB|/LP)×100[%], for example.

Unique features of the present example embodiment may include: 1) A step of providing the buffer layer 23 on the substrate 22 and a step of providing the piezoelectric film 28 on the buffer layer 23 are included. 2) A step of joining the piezoelectric film 28 of the multilayer body including the substrate 22, the buffer layer 23, and the piezoelectric film 28 to the support 33 and a step of removing the buffer layer 23 and the substrate 22 from the piezoelectric film 28 are included. 3) The mismatch between the lattice constant LS of the substrate 22 and the lattice constant LB of the buffer layer 23 satisfies (|LS−LB|/LS)×100[%]≤20[%], for example. 4) The mismatch between the lattice constant LB of the buffer layer 23 and the lattice constant LP of the piezoelectric film 28 satisfies (|LP−LB|/LP)×100[%]≤10[%], for example. These conditions can increase the crystallinity of the piezoelectric film 8 of the obtained acoustic wave device 1 more reliably. In addition, this increases the productivity for the acoustic wave device 1. The following describes these points.

In the present example embodiment, the buffer layer 23 is formed on the substrate 22 as illustrated in FIG. 3A. The mismatch between the lattice constant LS of the substrate 22 and the lattice constant LB of the buffer layer 23 is about 20% or less, for example. This condition increases the crystallinity of the buffer layer 23 more reliably. Next, the piezoelectric film 28 is formed on the buffer layer 23. The mismatch between the lattice constant LB of the buffer layer 23 and the lattice constant LP of the piezoelectric film 28 is about 10% or less, for example. This condition increases the crystallinity of the piezoelectric film 28 more reliably. This piezoelectric film 28 is joined to the support 33 as illustrated in FIG. 3D, and thus the wafer 32 is obtained. Next, as illustrated in FIG. 4B, the wafer 32 is singulated into individual pieces, and a plurality of piezoelectric substrates 2 are obtained. These processes can increase the crystallinity of the piezoelectric film 8 in each piezoelectric substrate 2 more reliably. Here, in relation to the crystallinity of the piezoelectric film, FWHM, that is the full width at half maximum of the X-ray intensity, is preferably about 0.1 or less, more preferably, about 0.01 or less, with respect to the (012) plane and its equivalent plane of LiNbO3 or LiTaO3 formed by using XRD, for example.

Note that the step of removing the buffer layer 23 and the substrate 22 from the piezoelectric film 28 illustrated in FIGS. 3C and 3D as described above may be performed by laser lift-off. Details of this process will be described as a first modification example of the first example embodiment.

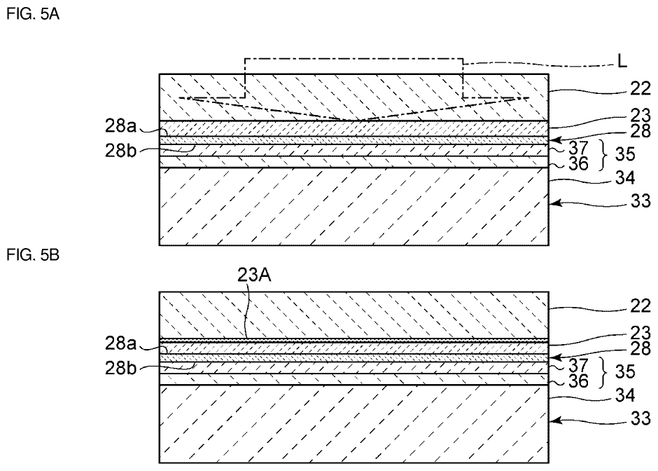

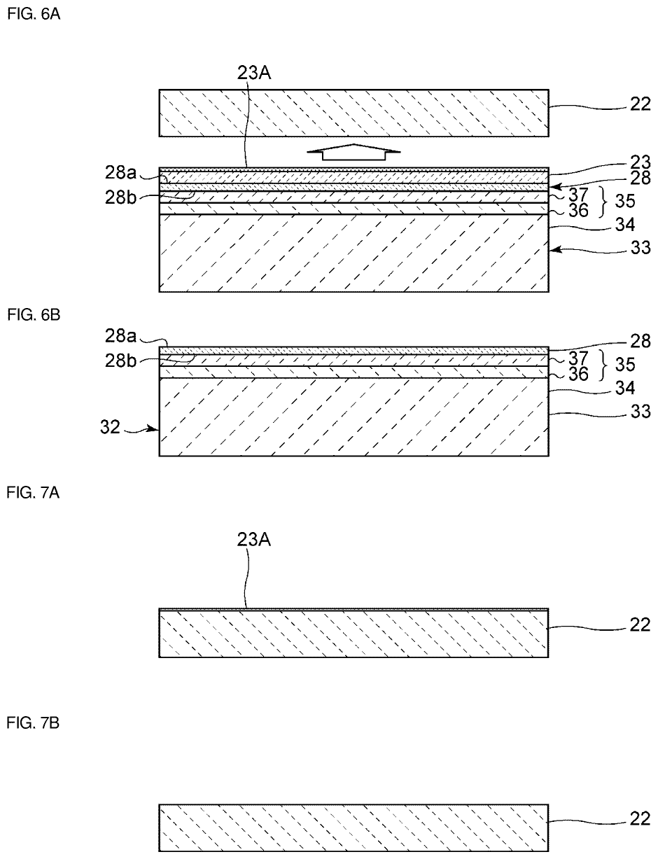

FIGS. 5A and 5B are schematic elevational sectional views for explaining a step of irradiating the buffer layer with laser light and related processes in the first modification example of the first example embodiment of the method of manufacturing the acoustic wave device. FIGS. 6A and 6B are schematic elevational sectional views for explaining a step of removing the buffer layer and the substrate from the piezoelectric film and related processes in the first modification example of the first example embodiment of the method of manufacturing the acoustic wave device.

As illustrated in FIG. 5A, the buffer layer 23 is irradiated with laser light L through the substrate 22. When the buffer layer 23 is irradiated with laser light L, a portion of the buffer layer 23 is decomposed. Next, the substrate 22 is separated from the buffer layer 23. In other words, the substrate 22 is removed from the piezoelectric film 28. Note that it is preferable that the band gap of the substrate 22 be smaller than the band gap of the buffer layer 23. This relationship increases the transmittance of the substrate 22 for the laser light L to pass through. This enables the buffer layer 23 to be irradiated with laser light L favorably.

When a portion of the buffer layer 23 is decomposed by irradiation with laser light L, a modified layer 23A is sometimes formed. The present example embodiment illustrates an example in which the modified layer 23A is formed. However, the modified layer 23A need not necessarily be formed.

Next, the buffer layer 23 and the modified layer 23A are removed from the piezoelectric film 28 as illustrated in FIG. 6B. To remove the buffer layer 23 and the modified layer 23A from the piezoelectric film 28, wet etching can be used, for example. Since a treatment such as wet etching is performed with the substrate 22 removed, the buffer layer 23 and the modified layer 23A can be removed easily. The wafer 32 is obtained through these processes.

In the step illustrated in FIG. 5A, it is preferable that the wavelength of the laser light L be about 150 nm or more and about 450 nm or less, for example. This enables portions of the buffer layer 23 near its surface close to the substrate 22 to be decomposed more reliably. This enables the substrate 22 to be more reliably and easily removed from the piezoelectric film 28.

Also in the present modification example, the first main surface 28a of the piezoelectric film 28 is cleaned after the buffer layer 23 is removed from the piezoelectric film 28. This process can reduce defects resulting from the residue of the buffer layer 23, which can increase the productivity. Next, high-temperature heat treatment, discharge treatment, or the like is performed on the piezoelectric film 28. This enables alignment of the polarization state of the piezoelectric film 28 more reliably.

In the present modification example, the steps other than the step of removing the buffer layer 23 and the substrate 22 from the piezoelectric film 28 can be performed as in the first example embodiment. Hence, the present modification example can also increase the crystallinity of the piezoelectric film more reliably in the obtained acoustic wave device.

After the steps illustrated in FIGS. 6A and 6B, a portion of the buffer layer 23 or the modified layer 23A sometimes remains on the substrate 22. Hence, after the buffer layer 23, the modified layer 23A, and the substrate 22 are removed from the piezoelectric film 28, the surface of the substrate 22 on which the buffer layer 23 was laminated may be cleaned. This process will be explained as a second modification example of the first example embodiment.

FIGS. 7A and 7B are schematic elevational sectional views for explaining the second modification example of the first example embodiment of the method of manufacturing the acoustic wave device.

As illustrated in FIG. 7A, the modified layer 23A remains on one surface of the substrate 22. In the present modification example, cleaning is performed on the surface of the substrate 22 where the modified layer 23A remains. In other words, cleaning is performed on the surface of the substrate 22 on which the buffer layer 23 illustrated in FIG. 5A and other figures was located. The modified layer 23A is removed by this process. Also in the case in which a portion of the buffer layer 23 remains on one surface of the substrate 22, this cleaning can remove the buffer layer 23.

This cleaning provides more reliably the substrate 22 illustrated in FIG. 7B on which neither the modified layer 23A nor the buffer layer 23 remains. This enables the substrate 22 to be reused favorably in the manufacturing of the acoustic wave device. This effectively increases the productivity.

In the present modification example, the steps other than the step of cleaning the surface of the substrate 22 on which the buffer layer 23 was located can be performed as in the first modification example. Hence, the present modification example can also increase the crystallinity of the piezoelectric film more reliably in the obtained acoustic wave device.

This step of cleaning the substrate 22 can be employed also in methods, other than the present modification example, of manufacturing an acoustic wave device according to an example embodiment of the present invention. For example, as illustrated in FIGS. 3C and 3D, the buffer layer 23 is removed by wet etching in the step of removing the buffer layer 23 and the substrate 22 from the piezoelectric film 28 in the first example embodiment. In this process, a portion of the buffer layer 23 sometimes remains on the substrate 22. Cleaning the surface of the substrate 22 on which the buffer layer 23 was located enables the substrate 22 to be reused favorably.

In an example embodiment of the present invention, it is preferable that the piezoelectric film 28 illustrated in FIG. 3A and other figures be formed by film deposition. Forming the piezoelectric film 28 by film deposition denotes forming it as a thin film. In the case in which the piezoelectric film 28 is formed by film deposition, the piezoelectric film 28 is a thin film before the thickness or the arithmetic mean roughness Ra of the piezoelectric film 28 is adjusted.

More specifically, in the step of forming the piezoelectric film 28, it is preferable that the thickness of the piezoelectric film 28 be about 1500 nm or less, and more preferable that it be about 400 nm or less, for example. In this case, in the case in which the thickness of the piezoelectric film 28 is adjusted by polishing or the like after the piezoelectric film 28 is formed, the amount of polishing or the like can be small. Alternatively, by setting the conditions when the piezoelectric film 28 is formed, the thickness of the piezoelectric film 28 can be adjusted, so that the piezoelectric film 28 can be a thin film with a desired thickness. This case does not require the thickness of the piezoelectric film 28 to be adjusted by polishing or the like after the piezoelectric film 28 is formed. This further increases the productivity.

In addition, the piezoelectric film 28 is provided on a multilayer body including the substrate 22 and the buffer layer 23 in an example embodiment of the present invention. Hence, also in the case in which the piezoelectric film 28 is formed by film deposition, the crystallinity of the piezoelectric film 28 can be increased more reliably. Hence, for example, the crystallinity of the piezoelectric film 8 in the acoustic wave device 1 illustrated in FIG. 1 can be increased more reliably.

The following shows examples of the material of each structural element or portion. When examples of the material of each structural element or portion in the piezoelectric substrate 2 or the wafer 32 are shown, the symbols before singulation into individual pieces are used for the symbol representing each structural element or portion.

The material of the piezoelectric film 28 may be, for example, either lithium niobate or lithium tantalate. In the case in which the material of the piezoelectric film 28 is lithium niobate or lithium tantalate, it is more preferable that the Euler angles (φ, θ, ψ) of lithium niobate or lithium tantalate be (within the range of 0°±10°, within the range of 120°±30°, within the range of 0°±10°) or angles (φ, θ, ψ) equivalent to these angles or that the Euler angles (φ, θ, ψ) be (within the range of 300±30, within the range of 90°±10°, within the range of 90°±10°) or the angles (φ, θ, ψ) equivalent to these angles, for example. These conditions enable the acoustic wave device 1 to achieve favorable electrical characteristics more reliably.

It is preferable that the material of the substrate 22 be one of lithium niobate, lithium tantalate, or sapphire. The piezoelectric film 28 is located indirectly above the substrate 22 with the buffer layer 23 interposed therebetween. In the case in which the material of the substrate 22 is one of the above materials, it is easy to epitaxially grow the piezoelectric film 28 when forming the piezoelectric film 28. This increases the crystallinity of the piezoelectric film 28 more reliably.

In the case in which the material of the substrate 22 is lithium niobate or lithium tantalate, it is more preferable that the Euler angles (φ, θ, ψ) of lithium niobate or lithium tantalate be (within the range of 0°±10°, within the range of 120°±30°, within the range of 0°±10°) or angles (φ, θ, ψ) equivalent to these angles. It is even more preferable that the material of the substrate 22 be either lithium niobate on a rotated Y-cut with a cut angle of 30°±30° or lithium tantalate on a rotated Y-cut with a cut angle of 30°±30°, for example. These conditions make it more likely that the Euler angles (φ, θ, ψ) of lithium niobate or lithium tantalate are (within the range of 0°±10°, within the range of 120°±30°, within the range of 0°±10°) or angles (p, 0, $) equivalent to these angles in the case in which the material of the piezoelectric film 28 is lithium niobate or lithium tantalate, for example.

Note that, for example, the Euler angles (φ, θ, ψ) of lithium niobate on a rotated Y-cut with a cut angle of 30° are (0°, 120°, 0°) or angles (φ, θ, ψ) equivalent to these angles.

Alternatively, in the case in which the material of the substrate 22 is lithium niobate or lithium tantalate, it is more preferable that the Euler angles (φ, θ, ψ) of lithium niobate or lithium tantalate be (within the range of 90°±10°, within the range of 90°±10°, within the range of 30°±30°) or angles (p, 0, $) equivalent to these angles, for example. It is even more preferable that the material of the substrate 22 be either lithium niobate on a rotated X-cut with a cut angle of 30°±30° or lithium tantalate on a rotated X-cut with a cut angle of 30°±30°, for example. These conditions make it more likely that the Euler angles (φ, θ, ψ) of lithium niobate or lithium tantalate are (within the range of 90°±10°, within the range of 90°±10°, within the range of 30°±30°) or angles (φ, θ, ψ) equivalent to these angles in the case in which the material of the piezoelectric film 28 is lithium niobate or lithium tantalate, for example.

Note that, for example, the Euler angles (φ, θ, ψ) of lithium niobate on a rotated X-cut with a cut angle of 30° are (90°, 90°, 30°) or angles (φ, θ, ψ) equivalent to these angles.

In the case in which the material of the substrate 22 is sapphire, it is more preferable that the surface of the substrate 22 on which the buffer layer 23 is formed be an r-plane illustrated in FIG. 8 or one close to this plane. Note that when the r-plane is expressed by Euler angles (φ, θ, ψ) to two decimal place, they are (0°, 122.23°, $), for example.

In the case in which the material of the substrate 22 is sapphire, specifically, it is more preferable that the Euler angles (φ, θ, ψ) of the sapphire be (within the range of 0°±10°, within the range of 122.23°±30°, any ψ) or angles (φ, θ, ψ) equivalent to these angles, for example. It is even more preferable that the Euler angles (φ, θ, ψ) of the sapphire be (within the range of 0°±10°, within the range of 122.23°±30°, within the range of 0°±10°) or angles (φ, θ, ψ) equivalent to these angles, for example. It is far more preferable that the Euler angles (φ, θ, ψ) of the sapphire be (0°, within the range of 122.23°±30°, 0°) or angles (φ, θ, ψ) equivalent to these angles, for example. These conditions make it more likely that the Euler angles (φ, θ, ψ) of lithium niobate or lithium tantalate are (within the range of 0°±10°, within the range of 120°±30°, within the range of 0° 10°) or angles (φ, θ, ψ) equivalent to these angles in the case in the material of the piezoelectric film 28 is lithium niobate or lithium tantalate, for example.

It is preferable that the material of the buffer layer 23 be one of metal, nitride, carbide, and oxide. In this case, it is easy to epitaxially grow the buffer layer 23 when forming the buffer layer 23. It is more preferable that the material of the buffer layer be one of aluminum, titanium, gallium nitride such as GaN, titanium oxide such as TiO₂, and aluminum nitride such as AlN. In this case, it is easy to epitaxially grow the piezoelectric film 28 when forming the piezoelectric film 28 on the buffer layer 23. This increases the crystallinity of the piezoelectric film 28 more reliably.

In an example embodiment of the present invention, the combination of the materials of the piezoelectric film 28, the buffer layer 23, and the substrate 22 is important. For example, in the case in which the combination of materials expressed as the piezoelectric film 28/the buffer layer 23/the substrate 22 is lithium niobate/zinc oxide/sapphire, the mismatch between the lattice constant LS of the substrate 22 and the lattice constant LB of the buffer layer 23 is about 31.8%, for example. The mismatch between the lattice constant LB of the buffer layer 23 and the lattice constant LP of the piezoelectric film 28 is about 17.6%, for example. In this case, the crystallinity of the piezoelectric film 28 cannot be sufficiently increased. The following shows example combinations of the materials of the piezoelectric film 28, the buffer layer 23, and the substrate 22.

In the case in which the material of the piezoelectric film 28 is lithium niobate or lithium tantalate, it is preferable that the materials of the buffer layer 23 and the substrate 22 be one of the following. Specifically, it is preferable that the combination of materials expressed as the buffer layer 23/the substrate 22 be one of gallium nitride/sapphire, gallium nitride/lithium niobate, titanium oxide/lithium niobate, and titanium oxide/lithium tantalate. This condition can effectively reduce the mismatch between the lattice constant LS of the substrate 22 and the lattice constant LB of the buffer layer 23 and the mismatch between the lattice constant LB of the buffer layer 23 and the lattice constant LP of the piezoelectric film 28. This can effectively increase the crystallinity of the piezoelectric film 28 more reliably.

However, the buffer layer 23 may be a multilayer body including a plurality of layers. For example, the buffer layer 23 may include a first buffer layer and a second buffer layer. In this case, the first buffer layer is located on the substrate 22. The second buffer layer is located on the first buffer layer. The piezoelectric film 28 is located on the second buffer layer.

In the case in which the material of the piezoelectric film 28 is lithium niobate or lithium tantalate, it is preferable that the combination of the materials of the first buffer layer and the second buffer layer be one of the following. Specifically, it is preferable that the combination of materials expressed as the second buffer layer/the first buffer layer be one of gallium nitride/aluminum nitride, titanium oxide/gallium nitride, and titanium oxide/titanium. This condition can further reduce the mismatch between the lattice constant LB of the buffer layer 23 and the lattice constant LP of the piezoelectric film 28. This can further increase the crystallinity of the piezoelectric film 28 more reliably.

Note that in the case in which the buffer layer 23 is a multilayer body, the lattice constant LB of the layer of the buffer layer 23 closest to the piezoelectric film 28 can be used to calculate the mismatch between the lattice constant LB of the buffer layer 23 and the lattice constant LP of the piezoelectric film 28.

In the case in which the material of the piezoelectric film 28 is lithium niobate or lithium tantalate, and in which the buffer layer 23 includes a first buffer layer and a second buffer layer, it is preferable that the combination of the materials of the buffer layer 23 and the substrate 22 is one of the following. Specifically, it is preferable that the combination of materials expressed as the second buffer layer/the first buffer layer/the substrate 22 be one of gallium nitride/aluminum nitride/sapphire, titanium oxide/gallium nitride/sapphire, titanium oxide/titanium/lithium niobate, and titanium oxide/titanium/lithium tantalate. This condition can further reduce the mismatch between the lattice constant LS of the substrate 22 and the lattice constant LB of the buffer layer 23 and the mismatch between the lattice constant LB of the buffer layer 23 and the lattice constant LP of the piezoelectric film 28. This can further increase the crystallinity of the piezoelectric film 28 more reliably.

It is preferable that the material of the support substrate 34 be one of glass, quartz crystal, sapphire, lithium tantalate, lithium niobate, silicon, silicon carbide such as SiC, gallium nitride such as GaN, gallium arsenic such as GaAs, diamond-like carbon (DLC), and aluminum oxide such as Al₂O₃.

The first layer 36 of the intermediate layer 35 is a silicon nitride layer. However, for example, the material of the first layer 36 is not limited to silicon nitride and can be, for example, a material mainly including silicon, aluminum oxide, silicon carbide, silicon nitride, silicon oxynitride, sapphire, lithium tantalate, lithium niobate, quartz crystal, alumina, zirconia, cordierite, mullite, steatite, forsterite, magnesia, diamond-like carbon (DLC), diamond, spinel, or sialon. The spinel mentioned here includes an aluminum compound including oxygen and at least one of Mg, Fe, Zn, Mn, or the like. Examples of the spinel mentioned above include MgAl₂O₄, FeAl₂O₄, ZnAl₂O₄, and MnAl₂O₄.

The second layer 37 of the intermediate layer 35 is a silicon oxide layer. However, the material of the second layer 37 is not limited to silicon oxide and can be, for example, a material mainly including glass, silicon oxide, silicon oxynitride, lithium oxide, tantalum pentoxide, or compounds including silicon oxide to which fluorine, carbon, or boron is added.

Note that the intermediate layer 35 may include only the first layer 36 or only the second layer 37. Alternatively, the intermediate layer 35 may be a multilayer body including three or more layers.

It is preferable that the intermediate layer 35 include at least one of a silicon nitride layer and a silicon oxide layer. This enables the acoustic wave device 1 illustrated in FIG. 4B to effectively confine the energy of the acoustic wave to the piezoelectric film 8 side.

More specifically, the silicon oxide layer is a low acoustic velocity layer. Specifically, the acoustic velocity of bulk waves propagating in the low acoustic velocity layer is lower than the acoustic velocity of bulk waves propagating in the piezoelectric film 28 illustrated in FIG. 4A. The silicon nitride layer is a high acoustic velocity layer. Specifically, the acoustic velocity of bulk waves propagating in the high acoustic velocity layer is higher than the acoustic velocity of acoustic waves propagating in the piezoelectric film 28. Similarly, in the case in which the material of the support substrate 34 is a preferred material mentioned above, the support substrate 34 is a high acoustic velocity layer.

Hence, in the case in which the intermediate layer 35 includes at least one of a silicon nitride layer and a silicon oxide layer, the acoustic wave device 1 illustrated in FIG. 4B includes a layer configuration including a high acoustic velocity layer, a low acoustic velocity layer, and a piezoelectric film 8 or a layer configuration including a high acoustic velocity layer and a piezoelectric film 8. These layer configurations enable the energy of the acoustic wave to be effectively confined to the piezoelectric film 8 side.

The following describes acoustic wave devices according to example embodiments of the present invention other than the first example embodiment, and methods of manufacturing the acoustic wave devices.

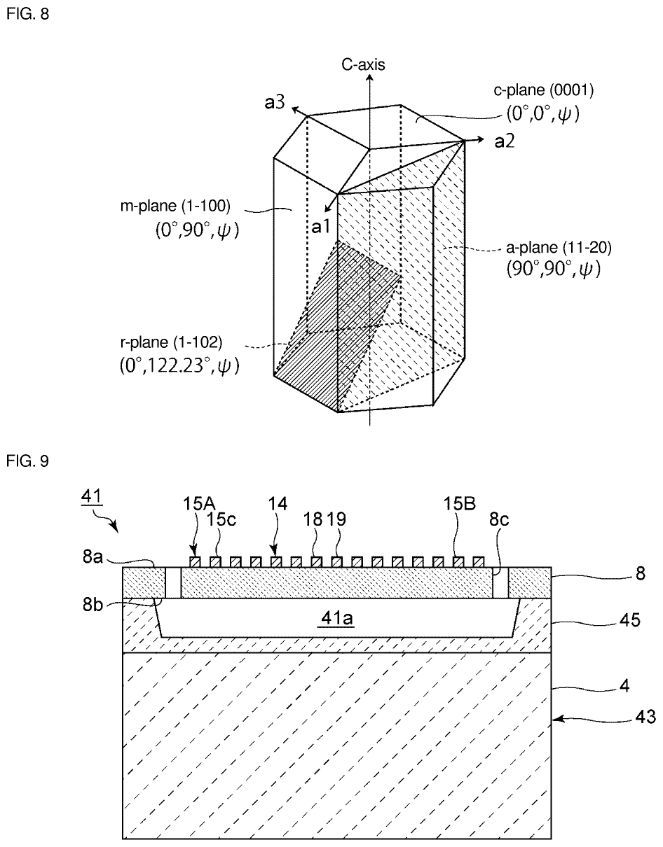

FIG. 9 is a schematic elevational sectional view of an acoustic wave device according to a second example embodiment.

The present example embodiment differs from the first example embodiment in that an intermediate layer 45 is a single dielectric layer. The present example embodiment differs from the first example embodiment also in that the piezoelectric film 8 has a plurality of through holes 8c, and that a cavity 41a is located between the piezoelectric film 8 and the support substrate 4. The plurality of through holes 8c communicate with the cavity 41a. Except for these points, an acoustic wave device 41 of the present example embodiment has a configuration the same as or similar to that of the acoustic wave device 1 of the first example embodiment.

The intermediate layer 45 has a recess. The piezoelectric film 8 is located on the intermediate layer 45 so as to cover the recess. This configuration forms a hollow portion. This hollow portion defines and functions as the cavity 41a. In the present example embodiment, a support 43 and the piezoelectric film 8 are located such that a portion of the support 43 and a portion of the piezoelectric film 8 face each other with the cavity 41a in between.

At least a portion of the functional electrode 14 overlap the cavity 41a of the support 43 in plan view. The term “in plan view” in this specification denotes viewing in the lamination direction of the support 43 and the piezoelectric film 8 from an upward position in FIG. 9. In FIG. 9, for example, of the support substrate 4 and the piezoelectric film 8, the piezoelectric film 8 is located on the upward side. In addition, the term “in plan view” in this specification has the same meaning as viewing in a main-surface opposing direction. The main-surface opposing direction refers to the direction in which the first main surface 8a and the second main surface 8b of the piezoelectric film 8 are opposed to each other. More specifically, the main-surface opposing direction is, for example, the direction normal to the first main surface 8a.

In the present example embodiment, the presence of the cavity 41a enables the energy of the acoustic wave to be effectively confined to the piezoelectric film 8 side.

The following describes an example of a method of manufacturing the acoustic wave device 41. Note that this manufacturing method is a second example embodiment of a method of manufacturing an acoustic wave device according to the present invention.

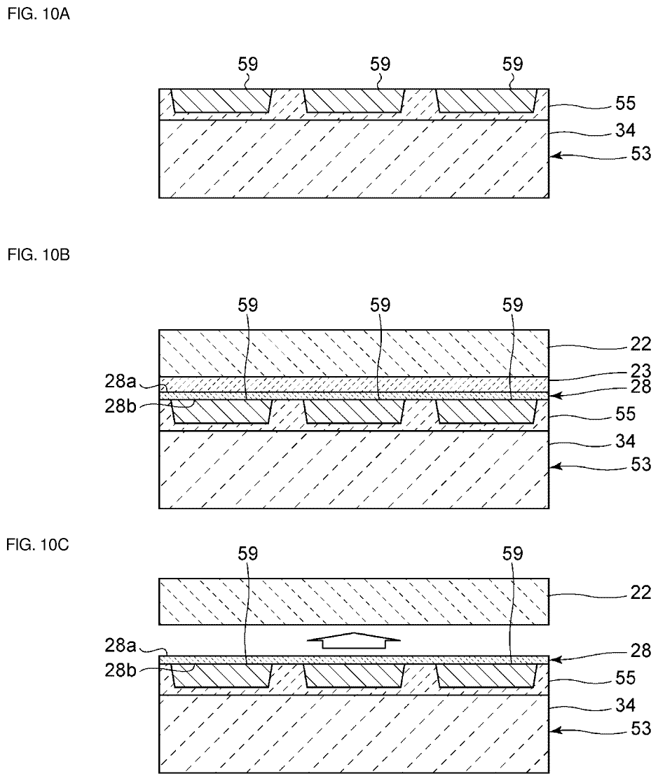

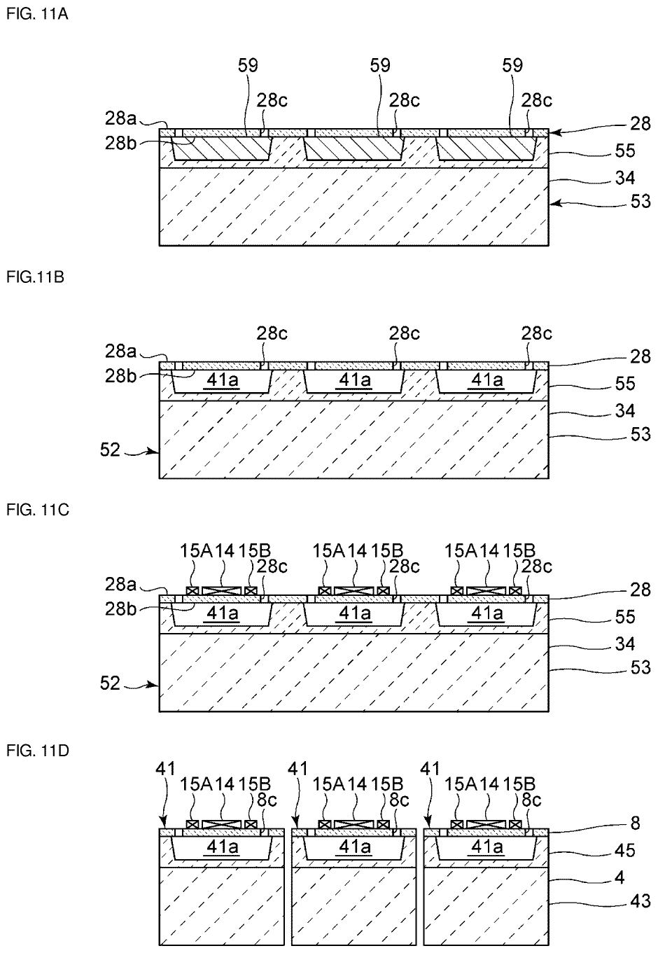

FIGS. 10A to 10C are schematic elevational sectional views for explaining the second example embodiment of the method of manufacturing the acoustic wave device. FIGS. 11A to 11D are simplified elevational sectional views for explaining the second example embodiment of the method of manufacturing the acoustic wave device.

As illustrated in FIG. 10A, in a step of preparing a support 53 in the present example embodiment, a plurality of sacrificial layers 59 are formed so as to be embedded in an intermediate layer 55. The material of the sacrificial layers 59 may be, for example, ZnO, SiO₂, Cu, a resin, or the like.

Specifically, for example, the plurality of sacrificial layers 59 may be formed on a substrate different from the support substrate 34. The sacrificial layers can be formed, for example, by photolithography using sputtering or vacuum vapor deposition or other methods. Next, the intermediate layer 55 is provided on the different substrate so as to cover the sacrificial layers 59. Next, the intermediate layer 55 is flattened. The flattening of the intermediate layer 55 may be performed, for example, by grinding, CMP, or the like. Next, the support substrate 34 is laminated on the intermediate layer 55, and then, the different substrate is separated from the intermediate layer 55. Note that the different substrate may be removed by polishing or the like.

Alternatively, for example, a layer defining and functioning as a portion of the intermediate layer 55 may be laminated on the support substrate 34, and then the plurality of sacrificial layers 59 may be formed on this layer. Next, a layer serving as the other portion of the intermediate layer 55 is provided so as to cover the plurality of sacrificial layers 59. After that, the plurality of sacrificial layers 59 are exposed from the intermediate layer 55 by polishing or the like.

Separately from these processes, the multilayer body including the substrate 22, the buffer layer 23, and the piezoelectric film 28, illustrated in FIG. 3A is prepared as in the first example embodiment. Next, as illustrated in FIG. 10B, the piezoelectric film 28 of the multilayer body including the substrate 22, the buffer layer 23, and the piezoelectric film 28 is joined to the support 53. Specifically, the second main surface 28b of the piezoelectric film 28 is joined to the intermediate layer 55 of the support 53.

Next, the buffer layer 23 and the substrate 22 are removed from the piezoelectric film 28 by wet etching. Specifically, the buffer layer 23 is removed by wet etching, and the substrate 22 is separated from the piezoelectric film 28 as illustrated in FIG. 10C. Note that to remove the buffer layer 23 and the substrate 22 from the piezoelectric film 28, for example, laser lift-off or the like may be used.

Next, the first main surface 28a of the piezoelectric film 28 is cleaned. Next, high-temperature heat treatment or discharge treatment is performed on the piezoelectric film 28. However, the cleaning of the first main surface 28a of the piezoelectric film 28 and the high-temperature heat treatment or discharge treatment of the piezoelectric film 28 are optional.

Next, the arithmetic mean roughness Ra of the first main surface 28a of the piezoelectric film 28 is adjusted by polishing or the like. However, the step of adjusting the arithmetic mean roughness Ra of the first main surface 28a of the piezoelectric film 28 is optional.

Next, as illustrated in FIG. 11A, a plurality of through holes 28c are formed in the piezoelectric film 28 so as to reach the plurality of sacrificial layers 59. The through holes 28c can be formed, for example, by reactive ion etching (RIE) or the like. Next, the sacrificial layers 59 are removed through the through holes 28c. More specifically, an etchant is introduced through the through holes 28c to remove the sacrificial layers 59 in the recesses of the intermediate layer 55. This process forms the plurality of cavities 41a as illustrated in FIG. 11B. A wafer 52 is obtained through these processes.

Next, as illustrated in FIG. 11C, a plurality of functional electrodes 14, a plurality of reflectors 15A, and a plurality of reflectors 15B are provided on the first main surface 28a of the piezoelectric film 28. Note that in addition to the functional electrodes 14 and the reflectors, wiring may be provided on the first main surface 28a when the functional electrodes 14 and the reflectors are provided. The functional electrodes 14, the reflectors, and the wiring can be formed, for example, by photolithography using sputtering or vacuum vapor deposition or other methods.

Next, the wafer 52 is singulated into individual pieces. The wafer 52 can be singulated into individual pieces, for example, by cutting with a dicing machine or other methods. A plurality of acoustic wave devices 41 can be obtained by this process, as illustrated in FIG. 11D.

Also in the present example embodiment, the piezoelectric film 28 is provided on the multilayer body including the substrate 22 and the buffer layer 23, as in the first example embodiment. The mismatch between the lattice constant LS of the substrate 22 and the lattice constant LB of the buffer layer 23 satisfies (|LS−LB|/LS)×100[%]≤20[%], for example. The mismatch between the lattice constant LB of the buffer layer 23 and the lattice constant LP of the piezoelectric film 28 satisfies (|LP−LB|/LP)×100[%]≤10[%], for example. These conditions can increase the crystallinity of the piezoelectric film 28 more reliably. This in turn can increase the crystallinity of the piezoelectric film 8 of the obtained acoustic wave device 41 more reliably.

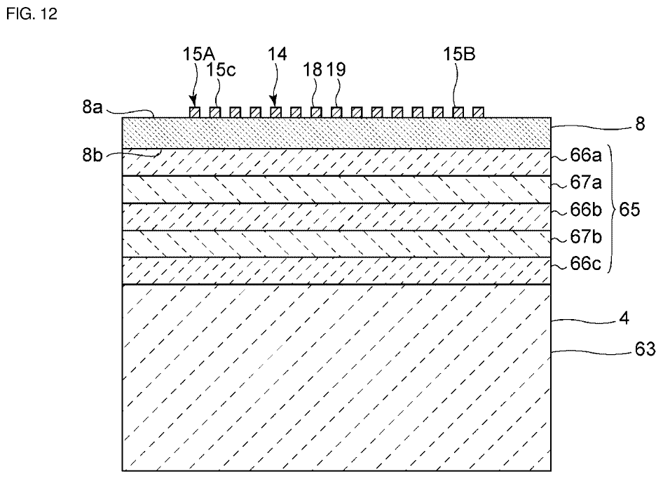

FIG. 12 is a schematic elevational sectional view of an acoustic wave device according to a third example embodiment.

The present example embodiment differs from the first example embodiment in that a support 63 is a multilayer body including a support substrate 4 and an acoustic reflection film 65. Except for this point, the acoustic wave device of the present example embodiment has a configuration the same as or similar to that of the acoustic wave device 1 of the first example embodiment.

The acoustic reflection film 65 is located on the support substrate 4. The piezoelectric film 8 is located on the acoustic reflection film 65. In the present example embodiment, the entire support substrate 4 and the entire piezoelectric film 8 are located on respective sides of the acoustic reflection film 65 and face each other. However, it is sufficient that the support substrate 4 and the piezoelectric film 8 be located such that at least a portion of the support substrate 4 and at least a portion of the piezoelectric film 8 are located on respective sides of the acoustic reflection film 65 and face each other. Then, it is sufficient that the functional electrode 14 and the acoustic reflection film 65 overlap each other in plan view.

The acoustic reflection film 65 includes a multilayer body of a plurality of acoustic impedance layers. Specifically, the acoustic reflection film 65 includes a plurality of low acoustic impedance layers and a plurality of high acoustic impedance layers. The low acoustic impedance layers have relatively low acoustic impedance. More specifically, the plurality of low acoustic impedance layers of the acoustic reflection film 65 include a low acoustic impedance layer 66a, a low acoustic impedance layer 66b, and a low acoustic impedance layer 66c.

The high acoustic impedance layers have relatively high acoustic impedance. More specifically, the plurality of high acoustic impedance layers of the acoustic reflection film 65 include a high acoustic impedance layer 67a and a high acoustic impedance layer 67b. The low acoustic impedance layers and the high acoustic impedance layers are alternately laminated. The low acoustic impedance layer 66a is a layer positioned closest to the piezoelectric film 8 in the acoustic reflection film 65.

The acoustic reflection film 65 includes three low acoustic impedance layers and two high acoustic impedance layers. However, it is sufficient that the acoustic reflection film 65 include at least one low acoustic impedance layer and at least one high acoustic impedance layer.

The material of the low acoustic impedance layers can be, for example, silicon oxide, aluminum, or the like. The material of the high acoustic impedance layers can be, for example, a metal such as platinum and tungsten, and a dielectric such as aluminum nitride, silicon nitride, and hafnium oxide.

In the present example embodiment, the presence of the acoustic reflection film 65 enables the energy of the acoustic wave to be effectively confined to the piezoelectric film 8 side.

The following describes an example of a method of manufacturing the acoustic wave device according to the third example embodiment. This manufacturing method is a third example embodiment of a method of manufacturing an acoustic wave device according to the present invention.

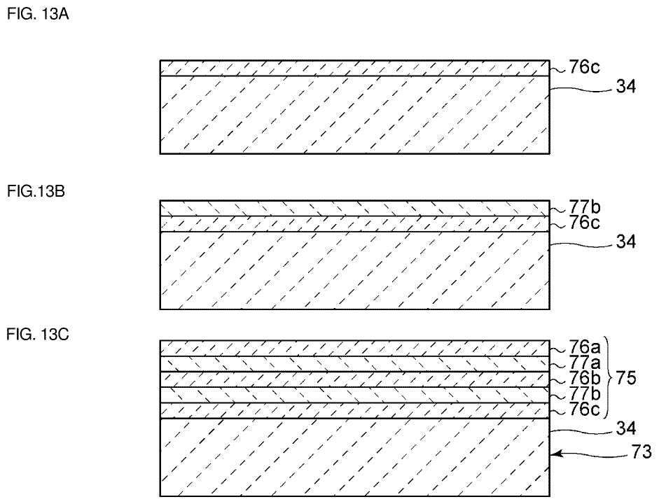

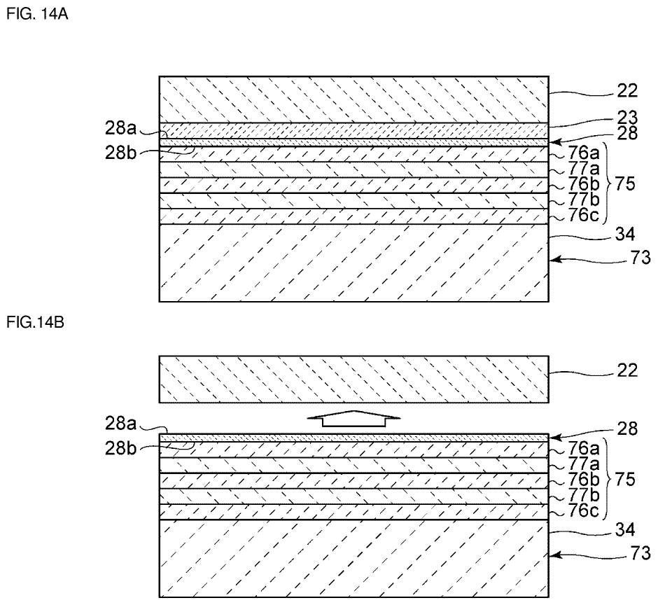

FIGS. 13A to 13C are schematic elevational sectional views for explaining a step of preparing a support in the third example embodiment of the method of manufacturing the acoustic wave device. FIGS. 14A and 14B are schematic elevational sectional views for explaining a step of joining a piezoelectric film to the support and a step of removing a buffer layer and a substrate from the piezoelectric film in the third example embodiment of the method of manufacturing the acoustic wave device.

As illustrated in FIG. 13A, a low acoustic impedance layer 76c is provided on the support substrate 34. Next, as illustrated in FIG. 13B, a high acoustic impedance layer 77b is provided on the low acoustic impedance layer 76c. In a manner as mentioned above, a low acoustic impedance layer and a high acoustic impedance layer are alternately laminated. Specifically, as illustrated in FIG. 13C, a low acoustic impedance layer 76b, a high acoustic impedance layer 77a, and a low acoustic impedance layer 76a are laminated in this order. An acoustic reflection film 75 is provided through these processes. The low acoustic impedance layers and the high acoustic impedance layers can be formed, for example, by sputtering, vacuum vapor deposition, or the like. A support 73 is obtained through these processes. Separately from these processes, the multilayer body including the substrate 22, the buffer layer 23, and the piezoelectric film 28 illustrated in FIG. 3A is prepared as in the first example embodiment. Next, as illustrated in FIG. 14A, the piezoelectric film 28 of the multilayer body including the substrate 22, the buffer layer 23, and the piezoelectric film 28 is joined to the support 73. Specifically, the second main surface 28b of the piezoelectric film 28 is joined to the acoustic reflection film 75 of the support 73.

Next, the buffer layer 23 and the substrate 22 are removed from the piezoelectric film 28 by wet etching. Specifically, the buffer layer 23 is removed by wet etching, and the substrate 22 is separated from the piezoelectric film 28 as illustrated in FIG. 14B. Note that to remove the buffer layer 23 and the substrate 22 from the piezoelectric film 28, for example, laser lift-off or the like may be used. The subsequent steps can be performed as in the first example embodiment.

Also in the present example embodiment, the piezoelectric film 28 is provided on the multilayer body including the substrate 22 and the buffer layer 23 as in the first example embodiment. The mismatch between the lattice constant LS of the substrate 22 and the lattice constant LB of the buffer layer 23 satisfies (|LS−LB|/LS)×100[%]≤20[%], for example. The mismatch between the lattice constant LB of the buffer layer 23 and the lattice constant LP of the piezoelectric film 28 satisfies (|LP−LB|/LP)×100[%]≤10[%], for example. These conditions can increase the crystallinity of the piezoelectric film 28 more reliably. This in turn can increase the crystallinity of the piezoelectric film 8 of the obtained acoustic wave device more reliably.

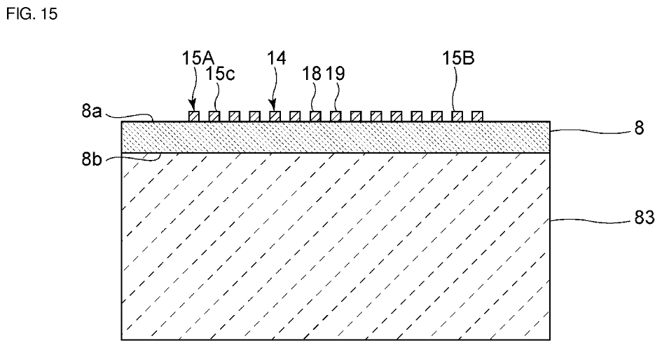

FIG. 15 is a schematic elevational sectional view of an acoustic wave device according to a fourth example embodiment.

The present example embodiment differs from the first example embodiment in that a support 83 includes only a support substrate. The piezoelectric film 8 is provided directly on the support substrate defining the support 83. Except for this point, the acoustic wave device of the present example embodiment has a configuration the same as or similar to that of the acoustic wave device 1 of the first example embodiment.

The following describes an example of a method of manufacturing the acoustic wave device according to the fourth example embodiment. This manufacturing method is a fourth example embodiment of a method of manufacturing an acoustic wave device according to the present invention.

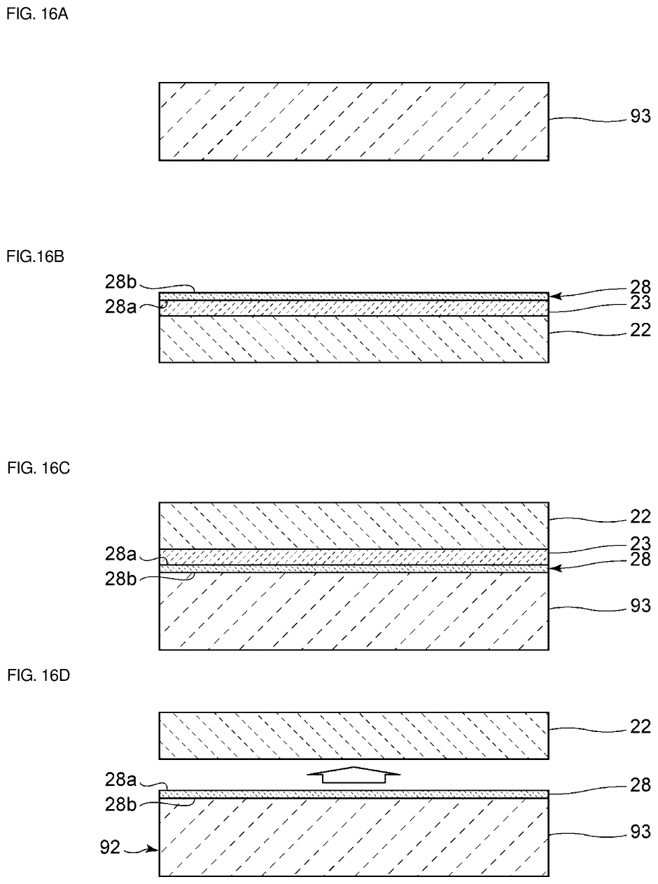

FIGS. 16A to 16D are schematic elevational sectional views for explaining the fourth example embodiment of the method of manufacturing the acoustic wave device according to the present invention.

As illustrated in FIG. 16A, a support 93 is prepared. Separately from this process, a multilayer body including the substrate 22, the buffer layer 23, and the piezoelectric film 28 is prepared as illustrated in FIG. 16B as in the first example embodiment. Next, the arithmetic mean roughness Ra of the second main surface 28b of the piezoelectric film 28 is made to be about 1 nm or less, for example, by CMP or the like. Note that the second main surface 28b is a main surface to be joined to a support substrate composing the support 93 illustrated in FIG. 16A.

Separately from this process, the arithmetic mean roughness Ra of the main surface, to be joined to the piezoelectric film 28, of the support substrate composing the support 93 is made to be about 1 nm or less, for example, by CMP or the like. Next, as illustrated in FIG. 16C, the second main surface 28b, having an arithmetic mean roughness Ra of about 1 nm or less, for example, of the piezoelectric film 28 and the main surface, having an arithmetic mean roughness Ra of 1 nm or less, for example, of the support substrate composing the support 93 are joined to each other by optical contact.

Next, the buffer layer 23 and the substrate 22 are removed from the piezoelectric film 28 by wet etching. Specifically, the buffer layer 23 is removed by wet etching, and the substrate 22 is separated from the piezoelectric film 28 as illustrated in FIG. 16D. A wafer 92 is obtained by this process. Note that to remove the buffer layer 23 and the substrate 22 from the piezoelectric film 28, for example, laser lift-off or the like may be used. The subsequent steps can be performed as in the first example embodiment.

Also in the present example embodiment, the piezoelectric film 28 is provided on the multilayer body including the substrate 22 and the buffer layer 23 as in the first example embodiment. The mismatch between the lattice constant LS of the substrate 22 and the lattice constant LB of the buffer layer 23 satisfies (|LS−LB|/LS)×100[%]≤20[%], for example. The mismatch between the lattice constant LB of the buffer layer 23 and the lattice constant LP of the piezoelectric film 28 satisfies (|LP−LB|/LP)×100[%]≤10[%], for example. These conditions can increase the crystallinity of the piezoelectric film 28 more reliably. This in turn can increase the crystallinity of the piezoelectric film 8 of the obtained acoustic wave device more reliably.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method of manufacturing an acoustic wave device, the method comprising:
preparing a substrate;
preparing a support;
providing a buffer layer on the substrate;
providing a piezoelectric film on the buffer layer;
joining the piezoelectric film of a multilayer body including the substrate, the buffer layer, and the piezoelectric film to the support; and
removing the buffer layer and the substrate from the piezoelectric film; wherein
(|LS−LB|/LS)×100[%]≤20[%]; and
(|LP−LB|/LP)×100[%]≤10[%];
where LS is a lattice constant of the substrate, LB is a lattice constant of the buffer layer, and LP is a lattice constant of the piezoelectric film.

2. The method of manufacturing an acoustic wave device according to claim 1, wherein
the buffer layer is formed on the substrate by epitaxial growth; and
the piezoelectric film is formed on the buffer layer by epitaxial growth.

3. The method of manufacturing an acoustic wave device according to claim 1, wherein the piezoelectric film is formed on the buffer layer by film deposition.

4. The method of manufacturing an acoustic wave device according to claim 1, wherein in the removing of the buffer layer and the substrate from the piezoelectric film, the buffer layer is removed by wet etching.

5. The method of manufacturing an acoustic wave device according to claim 1, wherein
a band gap of the buffer layer is smaller than a band gap of the substrate; and
in the removing of the buffer layer and the substrate from the piezoelectric film, separating the substrate from the buffer layer is performed by irradiating the buffer layer with laser light through the substrate, and the buffer layer is removed from the piezoelectric film after the separating.

6. The method of manufacturing an acoustic wave device according to claim 5, wherein a wavelength of the laser light is about 150 nm or more and about 450 nm or less.

7. The method of manufacturing an acoustic wave device according to claim 1, further comprising performing high-temperature heat treatment or discharge treatment on the piezoelectric film after the removing of the buffer layer and the substrate from the piezoelectric film.

8. The method of manufacturing an acoustic wave device according to claim 1, further comprising making, after the removing of the buffer layer and the substrate from the piezoelectric film, an arithmetic mean roughness Ra of a main surface of the piezoelectric film on which the buffer layer was laminated, about 1 nm or less.

9. The method of manufacturing an acoustic wave device according to claim 1, wherein a material of the substrate is one of lithium niobate, lithium tantalate, or sapphire.

10. The method of manufacturing an acoustic wave device according to claim 9, wherein
the material of the substrate is one of lithium niobate with Euler angles (φ, θ, ψ) of (within a range of 0°±10°, within a range of 120°±30°, within a range of 0°±10°) or angles equivalent thereto; lithium niobate with Euler angles (φ, θ, ψ) of (within a range of 90°±10°, within a range of 90°±10°, within a range of 30°±30) or angles equivalent thereto; lithium tantalate with Euler angles (φ, θ, ψ) of (within a range of 0°±10°, within a range of 120°±30°, within a range of 0°±10°) or angles equivalent thereto; lithium tantalate with Euler angles (φ, θ, ψ) of (within a range of 90°±10°, within a range of 90°±10°, within a range of 30°±30°) or angles equivalent thereto; or sapphire with Euler angles (φ, θ, ψ) of (within a range of 0°±10°, within a range of 122.23°±30°, any ψ) or angles equivalent thereto.

11. The method of manufacturing an acoustic wave device according to claim 1, wherein a material of the buffer layer is one of aluminum, titanium, gallium nitride, titanium oxide, or aluminum nitride.

12. The method of manufacturing an acoustic wave device according to claim 1, wherein
a material of the piezoelectric film is either lithium niobate or lithium tantalate; and
a combination of materials of the buffer layer and the substrate expressed as the buffer layer/the substrate is one of gallium nitride/sapphire, gallium nitride/lithium niobate, titanium oxide/lithium niobate, or titanium oxide/lithium tantalate.

13. The method of manufacturing an acoustic wave device according to claim 1, wherein
a material of the piezoelectric film is either lithium niobate or lithium tantalate;
the buffer layer is a multilayer body including a first buffer layer and a second buffer layer, the first buffer layer is located on the substrate, the second buffer layer is located on the first buffer layer, and the piezoelectric film is located on the second buffer layer; and
a combination of materials of the buffer layer and the substrate expressed as the second buffer layer/the first buffer layer/the substrate is one of gallium nitride/aluminum nitride/sapphire, titanium oxide/gallium nitride/sapphire, titanium oxide/titanium/lithium niobate, or titanium oxide/titanium/lithium tantalate.

14. The method of manufacturing an acoustic wave device according to claim 1, wherein
the support includes at least a support substrate; and
a material of the support substrate is one of glass, quartz crystal, sapphire, lithium tantalate, lithium niobate, silicon, silicon carbide, gallium nitride, gallium arsenic, diamond-like carbon, or aluminum oxide.

15. The method of manufacturing an acoustic wave device according to claim 1, wherein
the support includes only a support substrate;
the method further comprises:
making an arithmetic mean roughness Ra of a main surface of the support substrate, which is to be joined to the piezoelectric film, about 1 nm or less; and
making an arithmetic mean roughness Ra of a main surface of the piezoelectric film, which is to be joined to the support substrate, about 1 nm or less, and
in the joining of the piezoelectric film of the multilayer body including the substrate, the buffer layer, and the piezoelectric film to the support substrate, the main surface of the support substrate having the arithmetic mean roughness Ra of about 1 nm or less and the main surface of the piezoelectric film having the arithmetic mean roughness Ra of about 1 nm or less are joined to each other.

16. The method of manufacturing an acoustic wave device according to claim 1, wherein
the support is a multilayer body including a support substrate and an intermediate layer; and
in the joining of the piezoelectric film of the multilayer body including the substrate, the buffer layer, and the piezoelectric film to the support, the piezoelectric film is joined to the intermediate layer.

17. The method of manufacturing an acoustic wave device according to claim 16, wherein the intermediate layer includes at least one of a silicon oxide layer or a silicon nitride layer.

18. The method of manufacturing an acoustic wave device according to claim 16, wherein
in the preparing of the support, a sacrificial layer is provided to be embedded in the intermediate layer; and
the method further comprises removing the sacrificial layer after the removing of the buffer layer and the substrate from the piezoelectric film.

19. The method of manufacturing an acoustic wave device according to claim 1, wherein
the support is a multilayer body including a support substrate and an acoustic reflection film;
the acoustic reflection film includes a high acoustic impedance layer having a relatively high acoustic impedance and a low acoustic impedance layer having a relatively low acoustic impedance; and
in the joining of the piezoelectric film of the multilayer body including the substrate, the buffer layer, and the piezoelectric film to the support, the piezoelectric film is joined to the acoustic reflection film.
